(19) United States
(12) Patent Application Publication
(10) Pub. No.: US 2025/0241105 A1
(43) Pub. Date: Jul. 24, 2025

(54) DISPLAY DEVICE

(71) Applicant: InnoLux Corporation, Miao-Li County (TW)

(72) Inventors: Pei-Hsien LIU, Miao-Li County (TW); Chi-Han HSIEH, Miao-Li County (TW); Chiung-Chieh KUO, Miao-Li County (TW); Kuan-Hung KUO, Miao-Li County (TW)

(21) Appl. No.: 18/987,071

(22) Filed: Dec. 19, 2024

(30) Foreign Application Priority Data
Jan. 22, 2024 (CN) 202410089044.X

(51) Int. Cl. H10H 29/854; H10H 29/37; H10H 29/80; H10H 29/85; H10H 29/851

(52) U.S. Cl. CPC H10H 29/854; H10H 29/37; H10H 29/842; H10H 29/8512; H10H 29/8517

(57) ABSTRACT

A display device includes a first substrate, a light-emitting unit disposed on the first substrate, an intermediate layer on the light-emitting unit, and a color filter layer on the intermediate layer. The intermediate layer has a first refractive index n1, the color filter layer has a second refractive index n2, and the first refractive index n1 is less than the second refractive index n2.

### CROSS REFERENCE TO RELATED APPLICATIONS

This application claims priority of China Patent Application No. 202410089044.X, filed on Jan. 22, 2024, the entirety of which is incorporated by reference herein.

### BACKGROUND OF THE INVENTION

### Field of the Invention

The present invention relates to an electronic device, and, in particular, to a display device.

### Description of the Related Art

Due to the ongoing development of digital technology, electronic devices are widely used in all aspects of daily life. Display devices used in electronic devices include a light-emitting unit. In order to make a display device achieve a desired characteristic or a specific visual effect, a layered optical structure is usually provided on or under the light-emitting unit. The placement of the layered optical structure complicates the manufacturing of the display device, thereby increasing the manufacturing cost of the display device.

### BRIEF SUMMARY OF THE INVENTION

An embodiment of the present invention provides a display device includes a first substrate, a light-emitting unit disposed on the first substrate, an intermediate layer on the light-emitting unit, and a color filter layer on the intermediate layer. The intermediate layer has a first refractive index n1, the color filter layer has a second refractive index n2, and the first refractive index n1 is less than the second refractive index n2.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a cross-sectional schematic view of a display device according to an embodiment of the present disclosure.

FIG. 2 is a cross-sectional schematic view of a display device according to an embodiment of the present disclosure.

FIG. 3 is a cross-sectional schematic view of a display device according to another embodiment of the present disclosure.

FIG. 4 is a cross-sectional schematic view of a display device according to another embodiment of the present disclosure.

FIG. 5 is a cross-sectional schematic view of a display device according to another embodiment of the present disclosure.

FIG. 6 is a cross-sectional schematic view of a display device according to another embodiment of the present disclosure.

FIGS. 7A to 7D are schematic flowcharts of parts of the method of manufacturing the display device of FIG. 6.

### DETAILED DESCRIPTION OF THE INVENTION

The following is a detailed description of the electronic device according to the embodiment of the present disclosure. The following description provides many different examples for implementing different features of some embodiments of the disclosure. Specific examples of elements and arrangements are described below to brief and clear describe the present disclosure. These are, of course, merely examples and are not intended to be limiting. In addition, similar and/or corresponding symbols may be used in different embodiments to identify similar and/or corresponding elements in order to clearly describe the present disclosure. However, the use of these similar and/or corresponding symbols is only for the purpose of briefly and clearly describing some embodiments of the present disclosure and does not imply any correlation between the various embodiments and/or structures discussed.

It should be understood that embodiments may use relative terms such as “lower” or “bottom” or “higher” or “top” to describe the relative relationship of one element to another in the drawing. It will be understood that if the device in the drawing is flipped so that its top and bottom are reversed, the element described as being on the “lower” side will become the element on the “higher” side. The embodiments of the present disclosure are to be understood in conjunction with the drawings, and the drawings of the present disclosure are to be considered as part of the description of the disclosure.

Furthermore, when it is described that a first material layer is disposed on or above a second material layer, it may include a situation where the first material layer is in direct contact with the second material layer, or a situation where the first material layer may not be in direct contact with the second material layer, i.e., there may be a situation where the first material layer and the second material layer are separated by one or more other material layers. However, if it is described that the first material layer is directly disposed on the second material layer, it means that the first material layer is in direct contact with the second material layer.

It should be understood that, although the ordinal numbers “first”, “second”, etc. are used are used to modify elements. The ordinal numbers do not imply or represent numbers of the element (or elements). The ordinal numbers do not represent the order of one element over another or the order of manufacturing method. The ordinal numbers are only used to clearly distinguish two elements having the same name. The claims and the specification may not use the same terms. Therefore, the first element in the specification may be the second component in the claim.

In some embodiments of the present disclosure, terms related to joining and connecting, such as “connection”, “interconnection”, etc., unless otherwise defined, may refer to two structures being in direct contact, or may also refer to two structures not being in direct contact and there being other structures between the two structures. The terms “joint” and “connection” may also include the situation where both structures are movable or both structures are fixed. In addition, terms “electrical connection” and “coupling” include all direct and indirect means of electrical connection.

In the disclosure, the terms “about,” and “substantially” usually indicates a value of a given value or range that varies within 10%, or within 5%, or within 3%, or within 2%, or within 1%, or within 0.5%. The values given here are approximate values, that is, even if “about” and “substantially” are not specifically stated, the meaning of “about” and “substantially” can still be implied. In the disclosure, the term “A-B” refers to a range that includes A, B, and all values between A and B.

It should be understood that, in the following embodiments, features in several different embodiments can be replaced, reorganized, and combined without departing from the spirit of the present disclosure to complete other embodiments. The features of various embodiments may be combined and used in any combination as long as they do not violate the spirit of the invention or conflict with each other.

Unless defined otherwise, all technical and scientific terms used herein have the same meaning as commonly understood by one of ordinary skills in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In the present disclosure, directions are not limited to three axes of a rectangular coordinate system, such as X-axis, Y-axis, and Z-axis. The direction can be interpreted in a broader sense. For example, the X-axis, Y-axis, and Z-axis may be perpendicular to each other, or may represent different directions that are not perpendicular to each other. For illustrative purposes, in the following, the Z-axis direction is a normal direction of the display device. In the embodiment of the present disclosure, the cross-sectional schematic view refers to a schematic view of the display device taken along the Z-axis direction.

The electronic device of the present disclosure may include a display device, a backlight device, an antenna device, a sensing device, or a splicing device, but the present disclosure is not limited thereto. The electronic device maybe a bendable or flexible electronic device. The display device may be a non-self-luminous display device or a self-luminous display device. The antenna device may be a liquid crystal antenna device or a non-liquid crystal antenna device. The sensing device may be a sensing device for sensing capacitance, light, heat or ultrasonic, but the present disclosure is not limited thereto. The splicing device may be, for example, a display splicing device or an antenna splicing device, but the present disclosure is not limited thereto. It should be noted that the electronic device may be any combination of the foregoing, but the present disclosure is not limited thereto. In the following, a display device will be used as an electronic device or a splicing device to illustrate the disclosure, but the disclosure is not limited thereto. Electronic elements may include passive elements and active elements, such as capacitors, resistors, inductors, diodes, transistors, etc. The diodes may include light-emitting diodes or photodiodes. The light-emitting diodes may include, for example, organic light-emitting diodes (OLED), mini light-emitting diodes (mini LED), micro light-emitting diodes (micro LED), or quantum dot light-emitting diodes (quantum dot LED), but the present disclosure is not limited thereto.

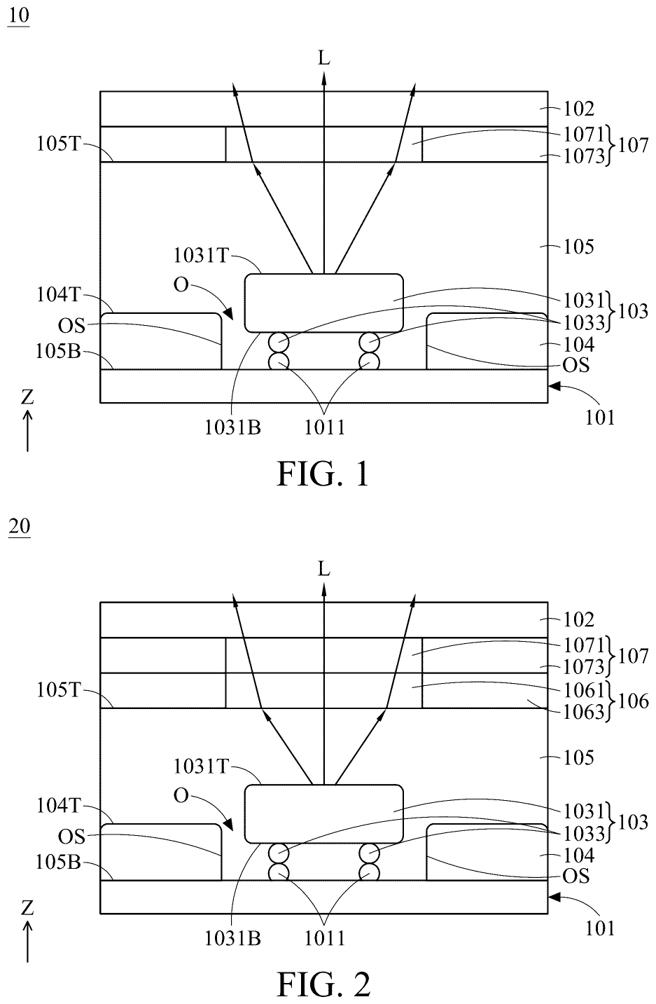

An aspect of the present disclosure is to provide a display device. FIG. 1 is a cross-sectional schematic view of a display device according to an embodiment of the present disclosure. As shown in FIG. 1, the display device 10 includes a first substrate 101, a light-emitting unit 103 disposed on the first substrate 101, an intermediate layer 105 disposed on the light-emitting unit 103, and a color filter layer 1071 disposed on the intermediate layer 105, wherein the intermediate layer 105 has a first refractive index n1 and the color filter layer 1071 has a second refractive index n2, and the first refractive index n1 is less than the second refractive index n2.

The first substrate 101 may include a flexible substrate, a rigid substrate, or a combination thereof, but the present disclosure is not limited thereto. In some embodiments, the first substrate 101 may include a light transmissive substrate or a semi-transmissive substrate. According to some embodiments, a material of the first substrate 101 may include glass, quartz, sapphire, ceramic, polyimide (PI), polycarbonate (PC), polyethylene terephthalate (PET), polypropylene (PP), other suitable materials, or any combination of thereof, but the disclosure is not limited thereto. In some embodiments, the first substrate 101 may include various elements, material layers, and/or combinations thereof for use in a display device. Examples of the elements may include a lead, a pad, a source electrode, a drain electrode, a common electrode, and other suitable elements. Examples of the material layers may include a polycrystalline silicon layer, an insulating layer, a buffer layer, and other suitable layers. In some embodiments, as shown in FIG. 1, the first substrate 101 may include a pad 1011. In some embodiments, the pad 1011 may include a metal, other suitable conductive materials, or any combination thereof. Examples of the metal may include gold, silver, copper, tin, nickel, other suitable metals, alloys thereof, or any combination thereof.

In some embodiments, the display device 10 of the present disclosure may further include a second substrate 102. The second substrate 102 is opposite to the first substrate 101. The light-emitting unit 103, the intermediate layer 105, and the color filter layer 1071 are between the second substrate 102 and the first substrate 101, as shown in FIG. 1. The second substrate 102 may have a similar structure and a similar material to the first substrate 101, so it will not be repeated herein.

The light-emitting unit 103 may include a light-emitting chip 1031 and at least one chip pad 1033. FIG. 1 illustrates the light-emitting unit 103 including the light-emitting chip 1031 and two chip pads 1033, but the present disclosure is not limited thereto. In some embodiments, the light-emitting unit 103 may include a sub-millimeter light-emitting diode (mini-LED), a micro-LED, a quantum dot LED (QLED/QDLED), or an organic light-emitting diode (OLED), but the present disclosure is not limited thereto. In some embodiments, the light-emitting chip 1031 may include an LED chip, but the present disclosure is not limited thereto. In some embodiments, the chip pad 1033 may include a metal, other suitable conductive materials, or any combination thereof. Examples of the metal are listed above and will not be repeated herein.

The light-emitting chip 1031 has an upper surface 1031T and a lower surface 1031B opposite to the upper surface 1031T. The at least one chip pad 1033 is disposed on the lower surface 1031B of the light-emitting chip 1031 and is between the lower surface 1031B of the light-emitting chip 1031 and the pad 1011 of the first substrate 101. The light-emitting unit 103 is disposed on the first substrate 101 by the chip pad 1033 of the light-emitting unit 103. In some embodiments, the light-emitting unit 103 is disposed on the first substrate 101 by a direct electrical connection between the chip pad 1033 and the pad 1011 of the first substrate 101, as shown in FIG. 1, but the present disclosure is not limited thereto. In the embodiment, the chip pads 1033 of the light-emitting unit 103 and the pad 1011 of the first substrate 101 may be directly bonded together by metal diffusion (e.g., Cu—Cu bonding), but the disclosure is not limited thereto. In some embodiments, the chip pads 1033 of the light-emitting unit 103 and the pad 1011 of the first substrate 101 may be bonded together by a solder. In some embodiments, the light-emitting unit 103 is disposed on the first substrate 101 by an indirect electrical connection between the chip pad 1033 and the pad 1011 of the first substrate 101.

The intermediate layer 105 is disposed on the upper surface 1031T of the light-emitting chip 1031. The intermediate layer 105 has an upper surface 105T and a lower surface 105B opposite to the upper surface 105T, and a distance between the upper surface 105T of the intermediate layer 105 and the first substrate 101 is greater than a distance between the lower surface 105B of the intermediate layer 105 and the first substrate 101. The upper surface 105T of the intermediate layer 105 is above the upper surface 1031T of the light-emitting chip 1031 and the lower surface 105B of the intermediate layer 105 is below the lower surface 1031B of the light-emitting chip 1031. In the embodiment, a portion of the intermediate layer 105 will be between the light-emitting unit 103 and the first substrate 101, as shown in FIG. 1.

The first refractive index n1 of the intermediate layer 105 may be greater than or equal to 1 and less than 1.5. In some embodiments, the first refractive index n1 of the intermediate layer 105 may be greater than or equal to 1 and less than or equal to 1.3. A light L emitted from the light-emitting unit 103 enters the intermediate layer 105. When the light L enters the intermediate layer 105, a relationship between an incidence angle and a refraction angle of the light L obeys Snell's Law. In some embodiments, the penetration rate of the intermediate layer 105 for visible wavelength light (light having a wavelength ranging from 380 nm to 780 nm) may be greater than or equal to 95%, or even greater than or equal to 98%. By making the penetration rate of the intermediate layer 105 greater than or equal to 95% for visible wavelength light, the light loss generated due to the light emitted from the light-emitting unit 103 passing through the intermediate layer 105 can be reduced, thereby improving the luminous efficiency of the display device 10.

In the embodiment where a portion of the intermediate layer 105 is between the light-emitting unit 103 and the first substrate 101 as shown in FIG. 1, the intermediate layer 105 has a coefficient of thermal expansion (CTE) of 25 to 30 ppm/K, a thermal conductivity coefficient that is greater than or equal to 1.0 W/mK, and a Young's modulus of 6 to 10 Gpa. By making the thermal expansion coefficient of the intermediate layer 105 between the light-emitting unit 103 and the first substrate 101 between 25 and 30 ppm/K, the intermediate layer 105 can reduce a risk of breakage of the light-emitting unit 103 and the first substrate 101 due to differences in expansion and contraction of the light-emitting unit 103 and the first substrate 101, thereby improving the lighting rate of the display device 10. By making the thermal conductivity coefficient of the intermediate layer 105 between the light-emitting unit 103 and the first substrate 101 greater than or equal to 1.0 W/mK, the intermediate layer 105 can dissipate heat to the environment and reduce losses to temperature-sensitive materials in the light-emitting unit 103, thereby increasing the life of the display device 10. By making the Young's modulus of the intermediate layer 105 between the light-emitting unit 103 and the first substrate 101 between 6 and 10 Gpa, the intermediate layer 105 can have sufficient mechanical stress to withstand a pressure from the outside, which in turn improves the reliability of the display device 10.

In some embodiments, the intermediate layer 105 may include a material having good flowability, good adhesion, and/or yellowing resistance ability. In some embodiments, the intermediate layer 105 may include a material having a viscosity between 5 and 10 cP, a tensile adhesive greater than 2500 kPa, and/or a yellowness index less than 1, but the present disclosure is not limited thereto. In embodiments where the intermediate layer 105 has the above characteristics, the intermediate layer 105 can bond the second substrate 102 to the first substrate 101 without the need for an adhesive layer.

In some embodiments, the intermediate layer 105 may include an epoxy resin, an acrylic resin, and/or combinations thereof, but the present disclosure is not limited thereto. In some embodiments, the intermediate layer 105 may further include silica balls, air, other suitable fillers, and/or any combination thereof to further reduce the first refractive index n1 of the intermediate layer 105.

The color filter layer 1071 having a second refractive index n2 is disposed on the upper surface 105T of the intermediate layer 105. In some embodiments, the color filter layer 1071 is included in a first optical layer 107. The first optical layer 107 may include the color filter layer 1071 and a shading layer 1073. In some embodiments, the first optical layer 107 may include a plurality of color filter layers 1071. The plurality of color filter layers 1071 may include a red filter layer (allowing red light to pass through), a blue filter layer (allowing blue light to pass through), a green filter layer (allowing green light to pass through), and/or a white filter layer (allowing white light to pass through). In embodiments where the first optical layer 107 includes a plurality of color filter layers 1071, each of the color filter layers 1071 may be the same or different from each other. In some embodiments, the second refractive index n2 of the color filter layer 1071 may be greater than or equal to 1.5 and less than or equal to 1.7. In the embodiment, the color filter layer 1071 may include a polymer material, an acrylic resin, an organic photoresist, or any combination of thereof, but the present disclosure is not limited thereto. The shading layer 1073 may include a dark-colored resin, a dark-colored photoresist, a dark-colored ink, a dark-colored pigment, or any combination of thereof, such as a black resin, a black photoresist, a black ink, a black pigment, or any combination of thereof, but the present disclosure is not limited thereto.

In some embodiments, the display device 10 of the present disclosure may further include a pixel definition layer 104. The pixel definition layer 104 may have an upper surface 104T. In some embodiments, the upper surface 104T of the pixel definition layer 104 may be between the upper surface 1031T and the lower surface 1031B of the light-emitting chip 1031, as shown in FIG. 1, but the present disclosure is not limited thereto. In some embodiments, the upper surface 104T of the pixel definition layer 104 may be above the upper surface 1031T of the light-emitting chip 1031. The pixel definition layer 104 may be on the first substrate 101 and includes an opening O. The opening O penetrates the pixel definition layer 104 and exposes a portion of the first substrate 101. The light-emitting unit 103 may be disposed on the first substrate 101 exposed by the opening O, as shown in FIG. 1. The opening O has a side wall OS. In some embodiments, such as embodiments in which the lower surface 105B of the intermediate layer 105 is below the lower surface 1031B of the light-emitting chip 1031, the intermediate layer 105 may be further filled between the side wall OS of the opening O and the light-emitting unit 103, as shown in FIG. 1, but the present disclosure is not limited thereto. In some embodiments, the opening O may correspond to the color filter layer 1071. That is, the projection of the opening O on the first substrate 101 may overlap the projection of the color filter layer 1071 on the first substrate 101, as shown in FIG. 1, but the present disclosure is not limited thereto.

In some embodiments, the display device of the present disclosure may further include a second optical layer. FIG. 2 is a cross-sectional schematic view of a display device 20 according to an embodiment of the present disclosure. The display device 20 includes a first substrate 101, a pixel definition layer 104 disposed on the first substrate 101 and having an opening O, a light-emitting unit 103 disposed on the first substrate 101 and in the opening O of the pixel definition layer 104, an intermediate layer 105 on the light-emitting unit 103, a first optical layer 107 on the intermediate layer 105, and a second optical layer 106 between the intermediate layer 105 and the first optical layer 107. The first substrate 101, the pixel definition layer 104, the light-emitting unit 103, the intermediate layer 105, and the first optical layer 107 of the display device 20 may be substantially the same as the first substrate 101, the pixel definition layer 104, the light-emitting unit 103, the intermediate layer 105, and the first optical layer 107 of the display device 10, so the second optical layer 106 will be further described below.

The second optical layer 106 may include a light conversion layer 1061 and a barrier layer 1063. The light conversion layer 1061 may be disposed between the intermediate layer 105 and the color filter layer 1071, and the barrier layer 1063 may be disposed between the intermediate layer 105 and the shading layer 1073, as shown in FIG. 2. In some embodiments, the light conversion layer 1061 may have a third refractive index n3. The first refractive index n1 of the intermediate layer 105 may be less than the third refractive index n3 of the light conversion layer 1061. In some embodiments, the third refractive index n3 of the light conversion layer 1061 may be greater than or equal to 1.5 and less than or equal to 1.7. In some embodiments, the light conversion layer 1061 may further include light conversion particles. Examples of the light conversion particles may include quantum dots, but the present disclosure is not limited thereto. In this embodiment, the light conversion particles may include cadmium selenide, indium phosphide, perovskite, or any combination of thereof, but the disclosure is not limited thereto.

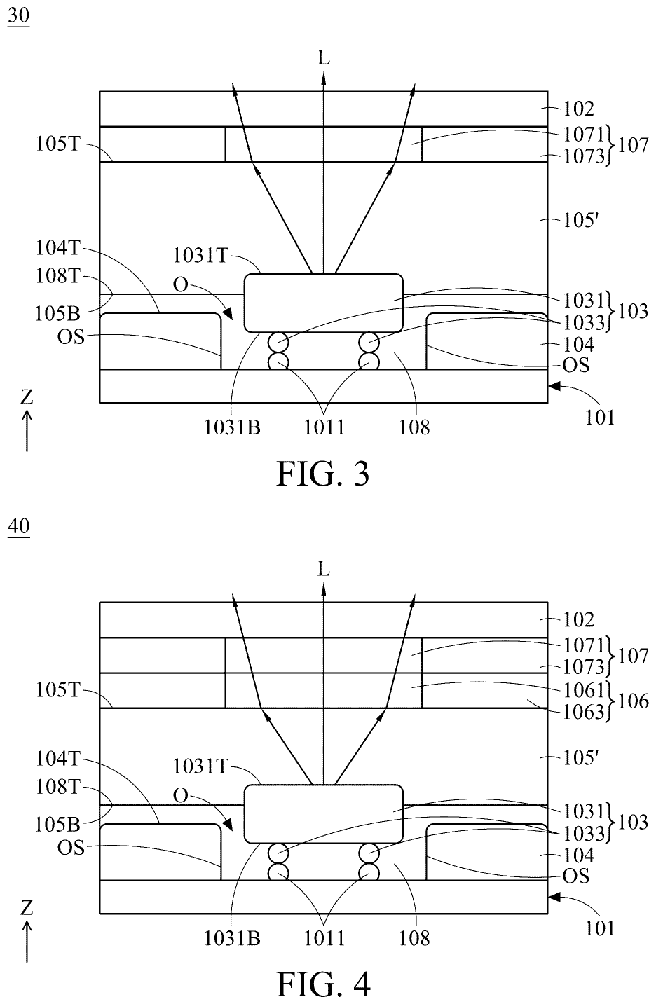

FIG. 3 is a cross-sectional schematic view of a display device 30 according to another embodiment of the present disclosure. The display device 30 includes a first substrate 101, a pixel definition layer 104 disposed on the first substrate 101 and having an opening O, a light-emitting unit 103 disposed on the first substrate 101 and in the opening O of the pixel definition layer 104, an intermediate layer 105′ on the light-emitting unit 103, a first optical layer 107 on the intermediate layer 105′, and an underfill layer 108 between the intermediate layer 105′ and the first substrate 101. In addition to the intermediate layer 105′ and the underfill layer 108, the first substrate 101, the pixel definition layer 104, the light-emitting unit 103, and the first optical layer 107 of the display device 30 may be substantially the same as the first substrate 101, the pixel definition layer 104, the light-emitting unit 103, and the first optical layer 107 of the display device 10, so the intermediate layer 105′ and the underfill layer 108 will be further described below.

Similar to the intermediate layer 105, the intermediate layer 105′ has an upper surface 105T and a lower surface 105B opposite to the upper surface 105T. The underfill layer 108 is disposed between the lower surface 105B of the intermediate layer 105′ and the first substrate 101. The upper surface 105T of the intermediate layer 105′ is above the upper surface 1031T of the light-emitting chip 1031, and the lower surface 105B of the intermediate layer 105′ is between the upper surface 1031T and the lower surface 1031B of the light-emitting chip 1031. The underfill layer 108 has an upper surface 108T, and the upper surface 108T of the underfill layer 108 is below the upper surface 1031T of the light-emitting chip 1031. In some embodiments, the upper surface 108T of the underfill layer 108 is coplanar with the lower surface 105B of the intermediate layer 105′, as shown in FIG. 3. In some embodiments, a portion of the light-emitting unit 103 may be embedded in the underfill layer 108. That is, in the display device 30, the underfill layer 108 is filled between the side wall OS of the opening O of the pixel definition layer 104 and the light-emitting unit 103.

The thermal expansion coefficient of the underfill layer 108 may be between 25 and 30 ppm/K. The thermal conductivity coefficient of the underfill layer 108 may be greater than or equal to 1.0 W/mK. The Young's modulus of the underfill layer 108 may be between 6 and 10 Gpa. The underfill layer 108 may include epoxy resin, polymer, and/or combinations thereof, but the present disclosure is not limited thereto. By making the thermal expansion coefficient of the underfill layer 108 between 25 and 30 ppm/K, the underfill layer 108 can reduce the risk of breakage of the light-emitting unit 103 and the first substrate 101 due to the difference in expansion and contraction between the light-emitting unit 103 and the first substrate 101, thereby improving the lighting rate of the display device 30. By making the thermal conductivity of the underfill layer 108 greater than or equal to 1.0 W/mK, the underfill layer 108 can dissipate heat to the environment and reduce losses to temperature-sensitive materials in the light-emitting unit 103, and thus increase the life of the display device 30. By making the Young's modulus of the underfill layer 108 between 6 and 10 Gpa, the underfill layer 108 can have sufficient mechanical stress to withstand the pressure from the outside, which in turn improves the reliability of the display device 30.

Similar to the intermediate layer 105, the first refractive index n1 of the intermediate layer 105′ may be greater than or equal to 1 and less than 1.5. In some embodiments, the first refractive index n1 of the intermediate layer 105′ may be greater than or equal to 1 and less than or equal to 1.3. A light L emitted from the light-emitting unit 103 enters the intermediate layer 105′. When the light L enters the intermediate layer 105′, a relationship between an incidence angle and a refraction angle of the light L obeys Snell's Law. In some embodiments, the penetration rate of the intermediate layer 105′ for visible wavelength light may be greater than or equal to 95%, or even greater than or equal to 98%.

In some embodiments, the intermediate layer 105′ may include materials having good flowability, good adhesion, and/or yellowing resistance ability. In some embodiments, the intermediate layer 105′ may include a material having a viscosity between 100 and 1000 cP, a tensile adhesive greater than 2500 kPa, and/or a yellowness index less than 1, but the present disclosure is not limited thereto. In embodiments where the intermediate layer 105′ has the above characteristics, the intermediate layer 105′ can bond the second substrate 102 and the first substrate 101 without the need for an adhesive layer.

In some embodiments, the intermediate layer 105′ may include an epoxy resin, an acrylic resin, and/or combinations thereof, but the disclosure is not limited thereto. In some embodiments, the intermediate layer 105′ may further include silica balls, air, other suitable fillers, and/or any combination thereof to further reduce the first refractive index n1 of the intermediate layer 105′.

FIG. 4 is a cross-sectional schematic view of a display device 40 according to another embodiment of the present disclosure. Except that the display device 40 further includes a second optical layer 106 as that of the display device 20, the display device 40 is substantially the same as the display device 30, and therefore will not be described again.

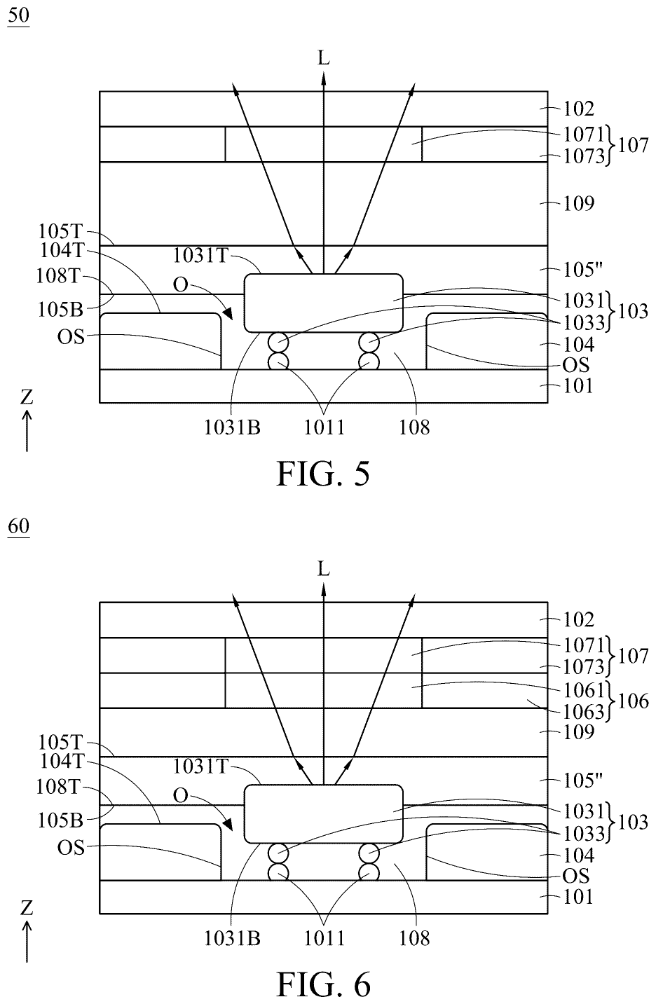

FIG. 5 is a cross-sectional schematic view of a display device 50 according to another embodiment of the present disclosure. The display device 50 includes a first substrate 101, a pixel definition layer 104 disposed on the first substrate 101 and having an opening O, a light-emitting unit 103 disposed on the first substrate 101 and in the opening O of the pixel definition layer 104, and an intermediate layer 105″ on the light-emitting unit 103, a first optical layer 107 on the intermediate layer 105″, an underfill layer 108 between the intermediate layer 105″ and the first substrate 101, and an adhesive layer 109 between the intermediate layer 105″ and the first optical layer 107. Except to the intermediate layer 105″ and the adhesive layer 109, the first substrate 101, the pixel definition layer 104, the light-emitting unit 103, the first optical layer 107, and the underfill layer 108 of the display device 50 may be substantially the same as the first substrate 101, the pixel definition layer 104, the light-emitting unit 103, the first optical layer 107, and the underfill layer 108 of the display device 30, so the intermediate layer 105″ and the adhesive layer 109 are further described below.

Similar to the intermediate layer 105′, the intermediate layer 105″ has an upper surface 105T and a lower surface 105B opposite to the upper surface 105T. The upper surface 105T of the intermediate layer 105″ is above the upper surface 1031T of the light-emitting chip 1031, and the lower surface 105B of the intermediate layer 105″ is between the upper surface 1031T and the lower surface 1031B of the light-emitting chip 1031. The intermediate layer 105″ is disposed between the underfill layer 108 and the adhesive layer 109. Specifically, the underfill layer 108 is disposed between the lower surface 105B of the intermediate layer 105″ and the first substrate 101, and the adhesive layer 109 is disposed between the upper surface 105T of the intermediate layer 105″ and the first substrate 101, as shown in FIG. 5. In some embodiments, the adhesive layer 109 may be disposed between the intermediate layer 105″ and the color filter layer 1071.

Similar to the intermediate layer 105′, the first refractive index n1 of the intermediate layer 105″ may be greater than or equal to 1 and less than 1.5. In some embodiments, the first refractive index n1 of the intermediate layer 105″ may be greater than or equal to 1 and less than or equal to 1.3. A light L emitted from the light-emitting unit 103 enters the intermediate layer 105″. When the light L enters the intermediate layer 105″, a relationship between an incidence angle and a refraction angle of the light L obeys Snell's Law. The adhesive layer 109 has a fourth refractive index n4. The first refractive index n1 of the intermediate layer 105″ may be smaller than the fourth refractive index n4 of the adhesive layer 109. In some embodiments, the fourth refractive index n4 of the adhesive layer 109 may be greater than or equal to 1.5 and less than or equal to 1.7.

In some embodiments, the penetration rate of the adhesive layer 109 for visible wavelength light may be greater than or equal to 95%, or even greater than or equal to 98%. In some embodiments, the adhesive layer 109 may include materials having good flowability, good adhesion, and/or yellowing resistance ability. In some embodiments, the adhesive layer 109 may include a material having a viscosity between 100 and 1000 cP, a tensile adhesive greater than 2500 kPa, and/or a yellowness index less than 1, but the present disclosure is not limited thereto. The adhesive layer 109 may include an optical clear adhesive (OCA), an optical clear resin (OCR), or a combination thereof, but the present disclosure is not limited thereto. Specifically, a material of the optical clear adhesive (OCA) or the optical clear resin (OCR) includes acrylic or epoxy resin, but the present disclosure is not limited thereto.

FIG. 6 is a cross-sectional schematic view of a display device 60 according to another embodiment of the present disclosure. Except that the display device 60 further includes a second optical layer 106 as that of the display device 20, the display device 60 is substantially the same as the display device 50, and therefore will not be described again.

The light L emitted from the light-emitting unit 103 will pass through the intermediate layer 105″ and then pass through the adhesive layer 109, the light conversion layer 1061 of the second optical layer 106, and/or the color filter layer 1071 of the first optical layer 107. By making the first refractive index n1 of the intermediate layer 105″ less than the second refractive index n2 of the color filter layer 1071, the third refractive index n3 of the light conversion layer 1061, and/or the fourth refractive index n4 of the adhesive layer 109, the light L emitted from the light-emitting unit 103 can be concentrated, thereby improving the light utilization rate of the light-emitting unit 103 and/or increasing the luminous efficiency of the display devices 10 to 60.

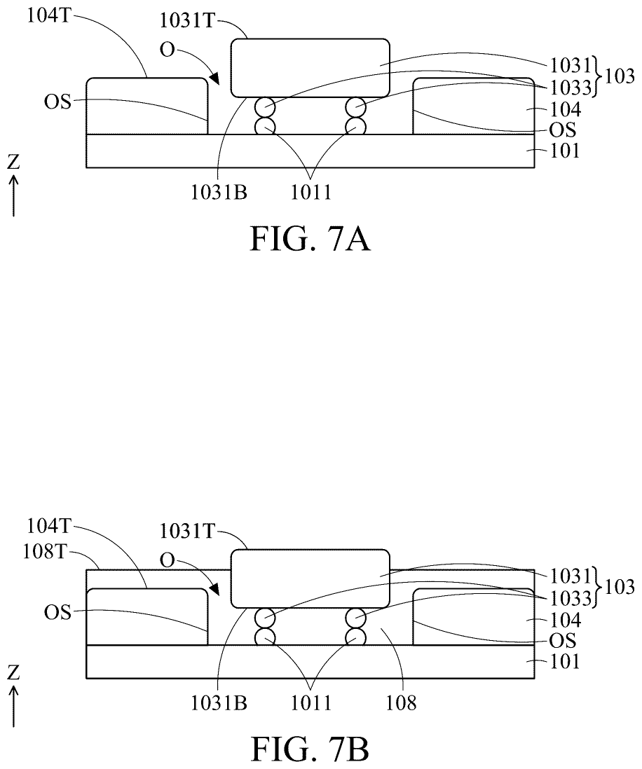

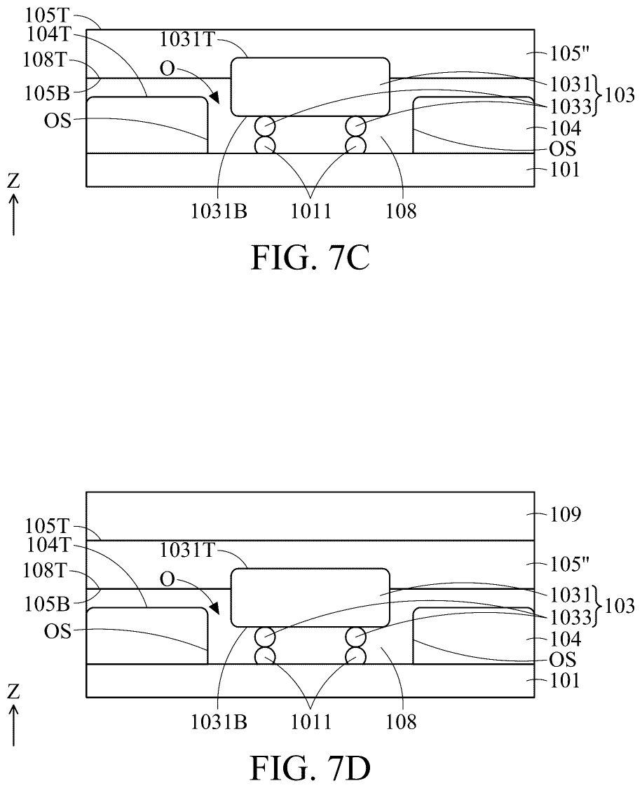

FIGS. 7A to 7D are schematic flowcharts of parts of the method of manufacturing the display device 60 of FIG. 6. The display device 60 is used as an example below to further illustrate the manufacturing method of the display device of the present disclosure with reference to FIGS. 7A to 7D.

The method of manufacturing the display device according to the present disclosure may include steps described below. A pixel definition layer 104 having an opening O therein is disposed on a first substrate 101 having a pad 1011. The opening O of the pixel definition layer 104 exposes the pad 1011 and a portion of the first substrate 101. The chip pad 1033 of the light-emitting unit 103 is bonded to the pad 1011 exposed by the opening O of the pixel definition layer 104 to dispose the light-emitting unit 103 on the first substrate 101 in the opening O of the pixel definition layer 104. The result structure as shown in FIG. 7A.

A filling material having good flowability and a viscosity between 5 and 6 cP, such as an epoxy resin, a high molecular polymer, and/or a combination thereof, is applied to the first substrate 101 to form a underfill layer 108 by spin coating, screen printing, chemical vapor deposition, physical vapor deposition, ink jet printing, slot coating, other suitable methods, or any combination thereof. In the Z-axis direction, a thickness of the underfill layer 108 may be thinner than a height of the light-emitting unit 103. That is, the upper surface 108T of the underfill layer 108 may be below the upper surface 1031T of the light-emitting chip 1031 of the light-emitting unit 103. During applying the filling material, the filling material having good flowability flows into a space between the side wall OS of the opening O of the pixel definition layer 104 and the light-emitting unit 103, so a portion of the light-emitting unit 103 will be embedded in the underfill layer 108, as shown in FIG. 7B.

A low refractive index material having a refractive index greater than or equal to 1 and less than 1.5, such as an epoxy resin, an acrylic resin, and/or a combination thereof, is formed on the underfill layer 108 to form the intermediate layer 105″ by spin coating, screen printing, chemical vapor deposition, physical vapor deposition, ink jet printing, slot coating, other suitable methods, or any combination thereof. In some embodiments, the low refractive index material may be an epoxy resin, an acrylic resin, and/or a combination thereof. In some embodiments, the low refractive index material may further include silica balls, other suitable fillers, and/or a combination thereof. In some embodiments, air may be included in the intermediate layer 105″ formed of the above low refractive index material. The lower surface 105B of the intermediate layer 105″ is between the upper surface 1031T and the lower surface 1031B of the light-emitting chip 1031. In some embodiments, the intermediate layer 105″ completely covers the upper surface 1031T and covers a portion of the side surface of the light-emitting chip 1031 of the light-emitting unit 103, as shown in FIG. 7C.

An adhesive material having a penetration rate of 95% or more for visible wavelength light, having good adhesion, and/or having yellowing resistance ability, such as an optically clear adhesive (OCA), an optically clear resin (OCR), or a combination thereof, is formed on the intermediate layer 105′ to form the adhesive layer 109 by spin coating, screen printing, chemical vapor deposition, physical vapor deposition, ink jet printing, slot coating, other suitable methods, or any combination thereof. The resulting structure is as shown in FIG. 7D. The adhesive layer 109 can be bonded to the second substrate 102 in subsequent steps. In some embodiments, the adhesive material may include a material having a viscosity between 100 and 1000 cP, a tensile adhesive greater than 2500 kPa, and/or a yellowness index less than 1, but the present disclosure is not limited thereto.

Finally, the second substrate 102, on which the second optical layer 106 and the first optical layer 107 are formed, is bonded by the adhesive layer 109 to complete the manufacture of the display device 60 as shown in FIG. 6, but the present disclosure is not limited thereto. In some embodiments, the second optical layer 106 on the second substrate 102 may be omitted. In some embodiments, a material having the properties of both the adhesive layer 109 and the intermediate layer 105″ may be selected to form the intermediate layer 105′ to replace the adhesive layer 109 and the intermediate layer 105″ to obtain the display device 30 or 40 having the structure shown in FIG. 3 or FIG. 4. In some embodiments, a material having the properties of all the adhesive layer 109, the intermediate layer 105″, and the underfill layer 108 may be selected to form the intermediate layer 105 to replace the adhesive layer 109, the intermediate layer 105″, and the underfill layer 108 to obtain a display device 10 or 20 having a structure as shown in FIG. 1 or FIG. 2.

A display device having the above structure has at least the following advantages: (1) concentrating the light emitted from the light-emitting unit in the light-emitting device, thereby increasing the light utilization rate of the light-emitting units and/or increasing the luminous efficiency of the light-emitting device; (2) reducing a risk of breakage between the light-emitting unit and the first substrate due to the difference in expansion and contraction of the light-emitting unit and the first substrate, thereby increasing the brightness of the display device; (3) improving the reliability of the display device; and (4) dissipating heat generated by the light-emitting unit to the environment, reducing losses to temperature-sensitive materials in the light-emitting unit, and thereby increasing the life of the display device. By integrating the adhesive layer and the intermediate layer, or by integrating the adhesive layer, the intermediate layer and the underfill layer, the display device of the present disclosure can be manufactured by fewer processes, thereby reducing production costs and reducing carbon emissions.

Although embodiments of the present disclosure and the advantages thereof have been disclosed as above, it should be understood that changes, substitutions and modifications may be made without departing from the spirit and scope of the disclosure. In addition, the protection scope of the present disclosure is not limited to the processes, machines, fabrications, compositions, devices, methods and steps in the specific embodiments described in the specification. According to the embodiments of the present disclosure, a person of ordinary skill in the art may understand that current or future processes, machines, fabrications, compositions, devices, methods and steps capable of performing substantially the same functions or achieving substantially the same results may be used in the embodiments of the present disclosure. Therefore, the protection scope of the present disclosure includes the above-mentioned processes, machines, fabrications, compositions, devices, methods and steps. In addition, each claims constitutes an individual embodiment, and a protection scope of the present disclosure also includes a combination of each claims and embodiment. As long as the features of each embodiments do not violate the spirit of the invention or conflict with each other, they can be mixed and matched arbitrarily.

What is claimed is:

1. A display device, comprising:
a first substrate;
a light-emitting unit disposed on the first substrate;
an intermediate layer on the light-emitting unit, wherein the intermediate layer has a first refractive index n1; and
a color filter layer on the intermediate layer, wherein the color filter layer has a second refractive index n2,
wherein the first refractive index n1 is less than the second refractive index n2.

2. The display device as claimed in claim 1, wherein the first refractive index n1 is greater than or equal to 1 and less than 1.5.

3. The display device as claimed in claim 1, wherein the second refractive index n2 is greater than or equal to 1.5 and less than 1.7.

4. The display device as claimed in claim 1, wherein a penetration rate of the intermediate layer for a visible wavelength light is greater than or equal to 95%.

5. The display device as claimed in claim 1, wherein a thermal conductivity coefficient of the intermediate layer is greater than or equal to 1.0 W/mK.

6. The display device as claimed in claim 1, wherein a Young's modulus of the intermediate layer is between 6 and 10 Gpa.

7. The display device as claimed in claim 1, further comprising a light conversion layer disposed between the intermediate layer and the color filter layer, wherein the light conversion layer has a third refractive index n3, and the first refractive index n1 is less than the third refractive index n3.

8. The display device as claimed in claim 7, wherein the third refractive index n3 for a visible wavelength light is greater than or equal to 1.5 and less than or equal to 1.7.

9. The display device as claimed in claim 7, wherein the light conversion layer further comprises light conversion particles.

10. The display device as claimed in claim 1, wherein the intermediate layer is between the first substrate and the light-emitting unit.

11. The display device as claimed in claim 1, further comprising a pixel definition layer on the first substrate and including an opening, wherein the light-emitting unit is disposed in the opening.

12. The display device as claimed in claim 11, wherein the intermediate layer is disposed in the opening.

13. The display device as claimed in claim 11, wherein a projection of the opening on the first substrate overlaps a projection of the color filter layer on the first substrate.

14. The display device as claimed in claim 1, further comprising an underfill layer between the intermediate layer and the first substrate, wherein a portion of the light-emitting unit is embedded in the underfill layer, and an upper surface of the underfill layer is below an upper surface of the light-emitting unit.

15. The display device as claimed in claim 14, wherein a Young's modulus of the underfill layer is between 6 and 10 Gpa.

16. The display device as claimed in claim 1, further comprising an adhesive layer disposed between the intermediate layer and the color filter layer, wherein the adhesive layer has a fourth refractive index n4, and the first refractive index n1 is smaller than the fourth refractive index n4.

17. The display device as claimed in claim 14, wherein a penetration rate of the adhesive layer for a visible wavelength light is greater than or equal to 95%.

18. The display device as claimed in claim 1, wherein a coefficient of thermal expansion (CTE) of the intermediate layer is 25 to 30 ppm/K.

19. The display device as claimed in claim 1, wherein the intermediate layer comprises a material having a viscosity between 5 and 10 cP, a tensile adhesive greater than 2500 kPa, and/or a yellowness index less than 1.

20. The display device as claimed in claim 1, wherein the intermediate layer further comprises silica balls, air, or a combination thereof.
